(19) United States
(12) Patent Application Publication
(10) Pub. No.: US 2004/0084411 A1
(43) Pub. Date: May 6, 2004

(54) Method of etching a silicon-containing dielectric material

(75) Inventors: Yan Du, San Jose, CA (US); Shashank Deshmukh, San Jose, CA (US); Meihua Shen, Fremont, CA (US); Steven Jones, Sunnyvale, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/286,297

(22) Filed: Oct. 31, 2002

(51) Int. Cl. H01L 21/461

(52) U.S. Cl. 216/67; 438/723

(57) ABSTRACT

Disclosed herein is a method of pattern etching a layer of a silicon-containing dielectric material. The method employs a plasma source gas comprising CH₂F₂, CF₄, and O₂, where a volumetric ratio of CH₂F₂ to CF₄ is within the range of about 1:2 to about 3:1, and where O₂ comprises about 2 to about 20 volume % of the plasma source gas. Etching is performed at a process chamber pressure within the range of about 4 mTorr to about 10 mTorr. The method provides a selectivity for etching a silicon-containing dielectric layer relative to photoresist of at least 2:1. The method also provides an etch profile sidewall angle ranging from about 84° to about 90° between the etched silicon-containing dielectric layer and an underlying horizontal layer in a semiconductor structure.

### BACKGROUND OF THE INVENTION

1. Field of the Invention

The present invention pertains to a method of etching a silicon-containing dielectric material. In particular, the invention pertains to a method of pattern etching a layer of a silicon-containing dielectric material for use as a hard mask for subsequent pattern etching of underlying layers in a semiconductor structure.

2. Brief Description of the Background Art

Silicon-containing dielectric materials (such as silicon nitride, silicon oxide, and silicon oxynitride) are often used as hard masks for pattern etching of underlying layers in a semiconductor structure. The silicon-containing dielectric layer itself is typically patterned using an overlying, patterned photoresist. Selectivity for etching the silicon-containing dielectric layer relative to an overlying, organic photoresist is important during the mask patterning step. As used herein, the term “selectivity” or “etch selectivity” refers to a ratio of the etch rate of a first material (e.g., a silicon-containing dielectric material) to the etch rate of a second material (e.g., photoresist) using a given plasma source gas and processing conditions.

Conventional plasma etch processes for pattern etching silicon-containing dielectric materials utilize a source gas which is a combination of CF₄ and CH₂F₂. While this etch chemistry typically provides good (at least 2:1) selectivity for etching the silicon-containing dielectric layer relative to the overlying photoresist, the resulting etch profile of the silicon-containing dielectric layer is typically tapered, as shown with reference to layer 110 in FIG. 1B. Because the silicon-containing dielectric layer will be used as a hard mask for subsequent pattern etching of underlying material layers, it is important that the patterned etch profile of the silicon-containing dielectric layer exhibit a sidewall angle, with respect to a horizontal base, which is as close to 90° as possible (typically about 88° to about 92°). Any deviation from a substantially 90° etch profile will be reflected in the etch profiles of the underlying layers.

### SUMMARY OF THE INVENTION

We have discovered a method of pattern etching a layer of a silicon-containing dielectric material which provides both good selectivity for etching the silicon-containing dielectric layer relative to photoresist and excellent etch profile control. The silicon-containing dielectric material is typically silicon nitride, but may alternatively be silicon oxide or silicon oxynitride, for example and not by way of limitation. The method is particularly useful for feature sizes in the range of about 0.13 μm to about 0.25 μm.

The source gas used for plasma etching the silicon-containing dielectric material includes CF₄, CH₂F₂, and O₂. Carbon tetrafluoride (CF₄) provides an excellent source of fluorine etchant species, while CH₂F₂ provides polymer generation and passivation of exposed photoresist surfaces, extending the lifetime of the photoresist. However, as the volumetric ratio of CH₂F₂ to CF₄ increases, the etch profile of the silicon-containing dielectric layer becomes more tapered. For example, in a pattern of lines and spaces, the width of a trench etched into the silicon-containing dielectric is wider at the top of the line than at the interface with the underlying substrate. As a result, the line produced after etching is wider at the interface with the underlying substrate than at the top of the line. The sidewall angle of the etched line with respect to the horizontal base typically may be 80° or less. The addition of a small amount Of O₂ (typically, less than 20% by volume of the plasma source gas) assists in profile control. However, the presence of O₂ in the plasma source gas reduces the selectivity for etching the silicon-containing dielectric material relative to the photoresist, resulting in more rapid erosion of the photoresist.

Therefore, it is important to achieve a balance between etch profile of the etched line and photoresist preservation. We have discovered that a volumetric ratio of CH₂F₂ to CF₄ in the plasma source gas within the range of about 1:2 to about 3:1 provides a good balance between etching and passivation, when used in combination with oxygen at a plasma source gas concentration of 20 volume % or less. Often, the volumetric ratio of CH₂F₂ to CF₄ ranges between about 1:2 and about 2:1. More typically, the volumetric ratio of CH₂F₂ to CF₄ ranges between about 1:1 and about 2:1. We have found that a plasma source gas comprising about 30 to about 70 volume % CH₂F₂, about 30 to about 70 volume % CF₄, and about 2 to about 20 volume % O₂ provides good (at least 2:1) selectivity for etching the silicon-containing dielectric layer relative to an overlying photoresist, as well as excellent etch profile control. More typically, the plasma source gas composition comprises about 50 to about 70 volume % CH₂F₂, about 30 to about 50 volume % CF₄, and about 5 to about 15 volume % O₂. Typically, the sidewall angle for a patterned line ranges from about 84° to about 90°.

The plasma source gas composition may further include a nonreactive diluent gas such as helium, argon, neon, xenon, or krypton, by way of example and not by way of limitation. Often, the nonreactive diluent gas is helium. Helium is typically present in the source gas at a concentration within the range of about 50 to about 70 volume %. Often, the plasma source gas is selected to include about 10 to about 25 volume % CH₂F₂, about 10 to about 25 volume % CF₄, about 2 to about 10 volume % O₂, and about 50 to about 70 volume % helium.

The etch method works particularly well when performed in a semiconductor processing chamber having a decoupled plasma source. The process chamber pressure during etching in such a processing chamber is typically within the range of about 4 mTorr to about 10 mTorr.

We have found that the etch method described above works especially well in combination with a photoresist which is sensitive to 248 nm radiation, of the kind commonly used in the art. The method provides a selectivity for etching a silicon-containing dielectric layer relative to the photoresist of about 2:1 or better. The method also provides a line etch profile sidewall angle ranging from 84° to 90° between the etched silicon-containing dielectric layer and an underlying horizontal layer in the semiconductor structure. In addition, the method provides an etched sidewall roughness of about 5 nm or less.

### BRIEF DESCRIPTION OF THE DRAWINGS

FIG. 1A shows a typical starting structure 100 which was used in the example embodiments described herein. Structure 100 includes the following layers, from top to bottom: a patterned photoresist layer 114 which is sensitive to 248 nm imaging radiation; a patterned bottom anti-reflective coating (BARC) layer 112; a silicon nitride layer 110; a tungsten layer 108; a polysilicon layer 106; and a gate layer 104, all deposited overlying a substrate 102.

FIG. 1B shows a schematic cross-sectional front view of structure 100 after pattern etching of silicon nitride layer 110, when a previously known, comparative method is used to etch the silicon nitride layer 110.

FIG. 1C shows a schematic front view of structure 100 after pattern etching of silicon nitride layer 110 using an embodiment method of the invention.

FIG. 2 shows a schematic cross-sectional front view of a silicon nitride layer 200, etched in a lines and spaces pattern, where the etched trench exhibits a tapered profile.

FIG. 3 shows a schematic cross-sectional front view of silicon nitride layer 300 etched in a lines and spaces pattern using an embodiment method of the invention, where the etched line exhibits a more vertical sidewall profile, where the angle between the line sidewall and a horizontal surface at the base of the line sidewall ranges between about 84° and about 90°.

FIG. 4 is a schematic of a CENTURA® DPS II™ (Model of Apparatus) etch chamber of the kind which was used to carry out the experimentation described herein.

### DETAILED DESCRIPTION OF EXEMPLARY EMBODIMENTS

Disclosed herein is a method of pattern etching a layer of a silicon-containing dielectric material. Exemplary processing conditions for performing various embodiments of the method of the invention are set forth below.

Although the method embodiments described below pertain to the use of a silicon-containing dielectric material as a hard mask in the etching of a gate structure, the etch chemistry and processing conditions described below can be used any time a silicon-containing dielectric material is used as a masking layer, for example, in the etching of a trench or contact via or other semiconductor feature.

As a preface to the detailed description, it should be noted that, as used in this specification and the appended claims, the singular forms “a”, “an”, and “the” include plural referents, unless the context clearly dictates otherwise.

I. An Apparatus for Practicing the Invention

The embodiment etch methods described herein are typically performed in a plasma etch chamber having a Decoupled Plasma Source (DPS) of the kind described by Yan Ye et al. at the Proceedings of the Eleventh International Symposium of Plasma Processing, May 7, 1996, and as published in the Electrochemical Society Proceedings, Volume 96-12, pp. 222-233 (1996). In particular, the embodiment example etch processes described herein were carried out in a CENTURA® DPS II™ plasma etch chamber available from Applied Materials, Inc., of Santa Clara, Calif. This apparatus used to carry out the etching described herein is discussed in detail below; however, it is contemplated that other plasma etch chamber apparatus known in the industry may be used to carry out the invention.

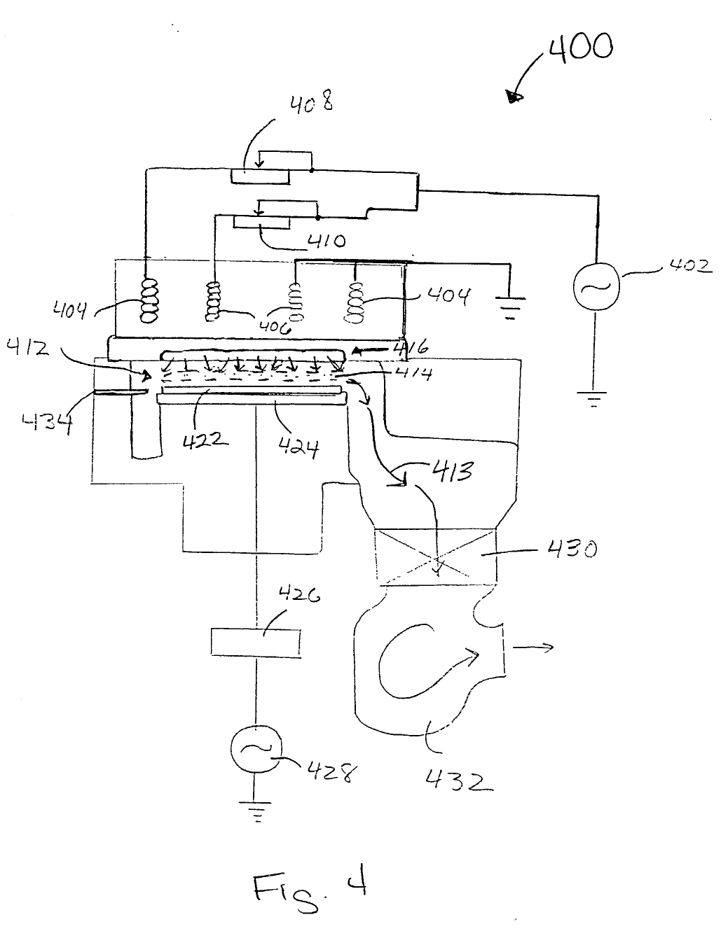

FIG. 4 shows a schematic of a cross-sectional view of a CENTURA® DPS II™ plasma etch chamber 400 of the kind which was used to carry out the etching processes described herein. During processing, a substrate 422 is introduced into the chamber 400 through a slit valve 434. The substrate 422 is held in place by means of a static charge generated on the surface of an electrostatic chuck (ESC) cathode 424, by applying a DC voltage to a conductive layer located under a dielectric film on the chuck surface (not shown). Etch gases are introduced into the chamber 400 by means of a gas distribution assembly 416. The etch chamber 400 uses an inductively coupled plasma RF source power 402, which is connected to an outer inductive coil 404 and an inner inductive coil 406 for generating and sustaining a high density plasma 414 in plasma processing region 412. Plasma source power 402 is split off into a first power distribution system 408, which provides power to outer coil 404, and a second power distribution system 410, which provides power to inner coil 406. The substrate 422 is biased by means of an RF source 428 and matching network 426. Power to the plasma source 402 and substrate biasing means 428 are controlled by separate controllers (not shown). Etch byproducts and excess processing gases 413 are exhausted from the chamber through throttle valve 430, by means of pump 432, which maintains the desired process chamber pressure. The temperature of the semiconductor substrate 422 is controlled using the temperature of the electrostatic chuck cathode 424 upon which the substrate 422 rests. Typically, a helium gas flow is used to facilitate heat transfer between the substrate and the pedestal.

Although the etch process chamber used to process the substrates described in the Examples presented herein is shown in schematic in FIG. 4, one skilled in the art may use any of the etch processors available in the industry, with some readily apparent adjustments. For example, the method of the invention may alternatively be performed in an etch processing apparatus wherein power to a plasma generation source and power to a substrate biasing means are supplied by a single power supply, such as the Applied Materials' MXP or MXP+ polysilicon etch chamber.

II. Exemplary Methods of Pattern Etching

A Silicon-Containing Dielectric Layer

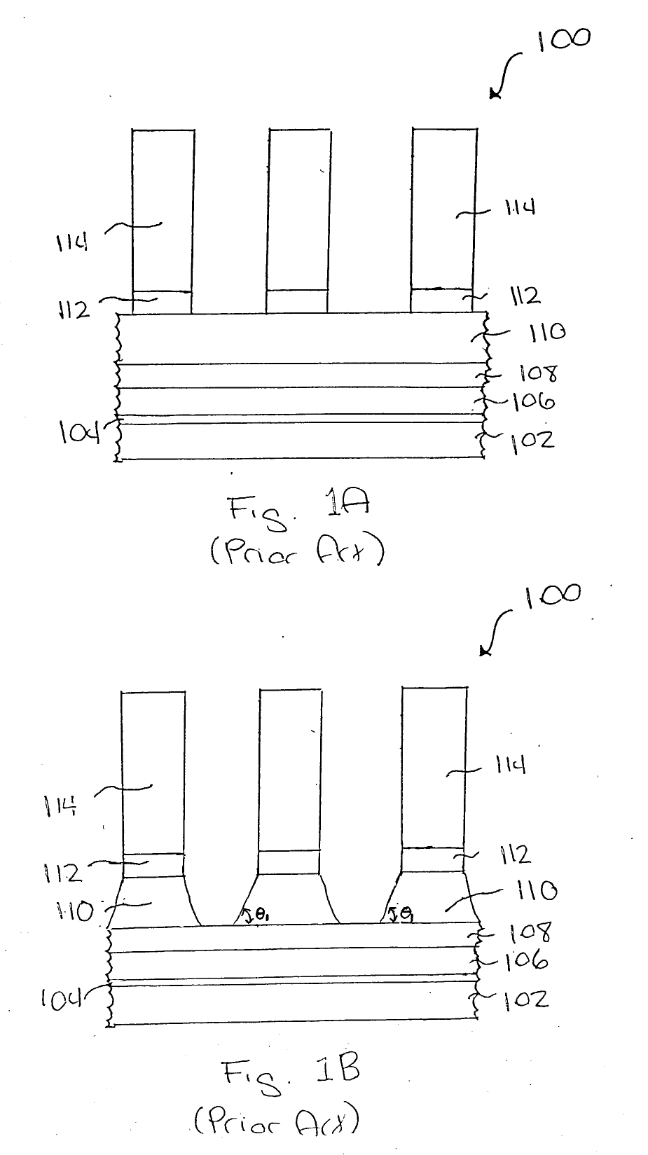

FIG. 1A shows a typical starting structure 100 for performing the embodiment etching methods described herein. Structure 100 includes the following layers, from top to bottom: a patterned 193 nm photoresist layer 114; a patterned bottom anti-reflective coating (BARC) layer 112; a silicon-containing dielectric layer 110; a tungsten layer 108; a polysilicon layer 106; and a gate oxide layer 104, all overlying a single-crystal silicon substrate 102. However, it is understood that, in practicing the invention, layers underlying the silicon-containing dielectric layer 110 may be different.

The various layers in the embodiment example semiconductor structure 100 are deposited using conventional deposition techniques known in the art, as follows.

Gate oxide layer 104 was a silicon oxide layer, which was formed by thermal oxidation, according to techniques known in the art. Gate oxide layer 104 had a thickness within the range of about 15 Å to 50 Å.

Polysilicon layer 106 was deposited by chemical vapor deposition (CVD), according to techniques known in the art. Polysilicon layer 106 had a thickness within the range of about 500 Å to about 2000 Å.

Tungsten layer 108 was deposited by CVD, according to techniques known in the art. Tungsten layer 108 had a thickness within the range of about 300 Å to about 1000 Å.

In the Examples described below, silicon-containing dielectric layer 110 was silicon nitride. However, silicon-containing dielectric layer 110 may alternatively comprise silicon oxide or silicon oxynitride. Optionally, silicon-containing dielectric layer 110 may be a dual layer, with an upper layer of silicon oxide and a lower layer of silicon nitride, for example, and not by way of limitation.

Silicon nitride layer 110 is typically deposited by low pressure CVD (LPCVD) or plasma-enhanced CVD (PECVD), according to techniques known in the art. Silicon nitride layer 110 typically has a thickness within the range of about 1000 Å to about 2500 Å.

Antireflective coatings are used in combination with photoresists to reduce standing waves and back-scattered light, so that the imaging within the photoresist can be better controlled. When the ARC layer lies beneath the photoresist layer, it is commonly referred to as a bottom antireflective coating (BARC). An organic BARC layer 112 is typically deposited by spin-on techniques known in the art. BARC layer 112 typically has a thickness within the range of about 500 Å to about 1500 Å.

Photoresist layer 114 is, in the present instance, a photoresist which is sensitive to radiation within the range of about 200 nm to about 300 nm. Typically, the photoresist is a chemically amplified version of an organic, polymeric-based composition which is available from a number of manufacturers, including AZ Electronic Materials (Somerville, N.J.) and Shipley, Inc. (Marlboro, Mass.). A typical film thickness for such a photoresist ranges from about 4000 Å to about 6000 Å. The thickness and patterning method for the photoresist layer 114 will depend on the particular photoresist material used and the pattern to be etched in the underlying substrate. In the present instance, for etching a pattern of lines and spaces which are 0.2 μm wide lines and 0.2 μm wide spaces through a 2000 Å thick layer of silicon nitride, the resist thickness is typically about 5000 Å. The maximum thickness of the photoresist is limited by the aspect ratio of the photoresist being developed and the particular characteristics of the photoresist used. To obtain advantageous results, the aspect ratio of the developed photoresist is typically about 4:1 or less; more typically, about 3:1 or less.

Patterned photoresist layer 114 is used as a mask to transfer the pattern to underlying BARC layer 112. Pattern etching of lines and spaces through an organic BARC layer 112 is typically performed using a plasma source gas including CF₄ and argon. Typical process conditions for pattern etching of BARC layer 110 in a decoupled plasma source etch chamber are as follows: 100 seem of CF₄; 100 seem of Ar; 4 mTorr to 20 mTorr process chamber pressure; 300 W to 1000 W plasma source power; 30 W to 100 W substrate bias power (about −60 V to −1000 V substrate bias voltage); and 40° C. to 80° C. substrate temperature. Etching time will depend on the composition and thickness of the particular BARC layer being etched. For an organic BARC layer having a thickness of 800 Å, the etch time is typically within the range of about 20 seconds to about 30 seconds.

III. Comparative Silicon Nitride Etch Example

The following comparative example was performed using the starting structure 100 shown in FIG. 1. Thicknesses of the various layers were as follows: a 5000 Å thick patterned 248 nm photoresist layer 114; a 600 Å thick patterned BARC layer 112; a 2000 Å thick silicon nitride layer 110; a 500 Å thick tungsten layer 108; a 1500 Å thick polysilicon layer 106; and a 15 Å thick silicon oxide gate layer, all deposited overlying a single-crystal silicon substrate 102.

After patterning of BARC layer 112 in the manner described above, the silicon nitride layer 110 was etched. Silicon nitride etching was performed in an Applied Materials' DPS II plasma etch chamber (shown in FIG. 4). Plasma etching of silicon nitride layer 110 was performed using the following plasma source gas composition and etch process conditions: 30 sccm CF₄; 60 sccm CH₂F₂; 4 mTorr process chamber pressure; 800 W plasma source power; 250 W substrate bias power; and a 60° C. substrate temperature.

FIG. 1B shows a schematic cross-sectional front view of the structure 100 after pattern etching of silicon nitride layer 108, when etching was performed using the CF₄/CH₂F₂/He etch chemistry and process conditions set forth above. Note the tapered profile of etched silicon nitride layer 108, where the line sidewall angle θ1 was about 78°.

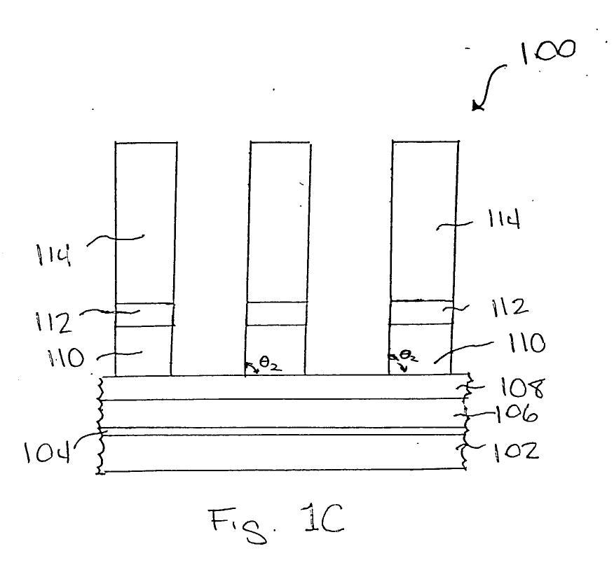

FIG. 2 is a schematic drawing based on a photomicrograph taken of a silicon nitride layer 200, etched in a lines and spaces pattern, where etching was performed using the CF₄/CH₂F₂/He etch chemistry and process conditions set forth above. FIG. 2 shows a schematic cross-sectional front view of silicon nitride layer 200. The etched line exhibits the tapered profile described above.

Because the silicon-containing dielectric layer will be used as a hard mask for subsequent pattern etching of underlying material layers, it is important that the patterned etch profile of the silicon-containing dielectric layer exhibit a sidewall angle, with respect to a horizontal base, which is as close to 90° as possible. Any non-uniformity in the etch profile of the mask opening will be reflected in the etch profiles of the underlying layers.

Therefore, we needed to a develop a method of pattern etching a layer of silicon-containing dielectric material which provides a vertical (i.e., as close to 90° as possible, and typically ranging between about 88° and about 92°) etch profile.

IV. Invention Embodiment Examples

We have found that the addition of a small amount of O₂ (typically, less than 20% by volume of the plasma source gas) provides excellent profile control, without significantly suppressing the etch rate of the silicon-containing dielectric material. A volumetric ratio of CH₂F₂ to CF₄ in the plasma source gas within the range of about 1:2 to about 2:1 was found to provide a good balance between etching and passivation, when used in combination with oxygen at a plasma source gas concentration of 20 volume % or less.

The following examples were performed using the starting structure 100 shown in FIG. 1. Thicknesses of the various layers were as follows: a 5000 Å thick patterned 248 nm photoresist layer 114; a 600 Å thick patterned organic BARC layer 112; a 2000 Å thick silicon nitride layer 110; a 500 Å thick tungsten layer 108; a 1500 Å thick polysilicon layer 106; and a silicon oxide gate layer 104, all deposited overlying a single-crystal silicon substrate 102.

After patterning of BARC layer 112 in the manner previously described, a silicon nitride layer 110 was etched. Silicon nitride etching was performed in the same Applied Materials' DPS II plasma etch chamber referred to with respect to the comparative example. Silicon nitride etch process conditions which were used during each experiment are presented in Table One, below.

TABLE ONE
Process Conditions Used During Etching of Silicon Nitride

| Process Parameter | Run #1 | Run #2 | Run #3 | Run #4 | Run #5 | Run #6 |
|---|---|---|---|---|---|---|
| CH₂F₂ Flow Rate (sccm) | 60 | 60 | 50 | 60 | 30 | 60 |
| CF₄ Flow Rate (sccm) | 30 | 30 | 30 | 30 | 15 | 30 |
| O₂ Flow Rate (sccm) | 15 | 5 | 5 | 5 | 5 | — |
| He Flow Rate (sccm) | — | — | — | — | 300 | — |
| Process Chamber | 4 | 4 | 4 | 4 | 4 | 4 |
| Pressure (mTorr) | | | | | | |
| Plasma Source Power (W) | 800 | 800 | 800 | 1200 | 1200 | 800 |
| Substrate Bias Power (W) | 250 | 250 | 250 | 250 | 250 | 250 |
| Substrate Temp. (° C.) | 60 | 60 | 60 | 60 | 60 | 60 |
| Etch Time (sec) | 75 | 70 | 72 | 57 | 65 | 60 |
| SiₓN_{y}: PR Selectivity, | 2.2 | 5.6 | 2.7 | 4 | — | 6.7 |
| no overetch* | | | | | | |
| SiₓN_{y}: PR Selectivity, | — | — | 2 | 2.4 | 1.7 | — |
| w/50% overetch** | | | | | | |
| Etch Profile Angle (θ) | 88 | 84 | 85 | 86 | 87 | 78 |

*Silicon nitride: photoresist etch selectivity, with no overetch step.
**Silicon nitride: photoresist etch selectivity, with 50% overetch. (Overetch process was the same as the main etch.)

The Run # 6 data are presented as a comparison, to show the tapered etch profile angle which is obtained when the plasma source gas does not include oxygen.

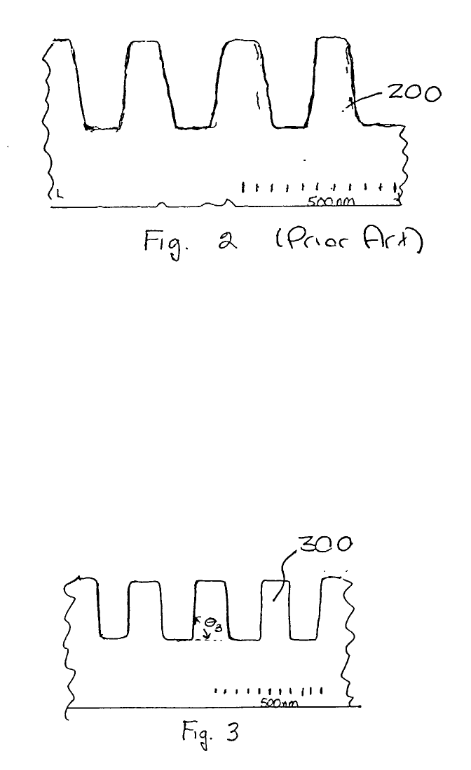

FIG. 1C shows a schematic cross-sectional front view of the structure 100 after pattern etching of silicon nitride layer 108 using a method of the invention which provided a nearly vertical etch profile exhibiting etch profile angle θ₂. FIG. 3 shows a schematic cross-sectional front view of silicon nitride layer 300 etched in a lines and spaces pattern using an embodiment method of the invention, where the etched line exhibits a vertical sidewall profile, where the angle θ3 between the line sidewall and a horizontal surface at the base of the sidewall ranges between about 84° and about 92°.

According to the present method embodiment, etching of a silicon-containing dielectric material is typically performed using a plasma generated from a source gas which includes CH₂F₂, CF₄, and O₂, where a volumetric ratio of CH₂F₂ to CF₄ is within the range of about 1:2 to about 3:1, and where O₂ is comprises about 2 to about 20 volume % of the plasma source gas. Often, the volumetric ratio of CH₂F₂ to CF₄ ranges between about 1:2 and about 2:1. More typically, the volumetric ratio of CH₂F₂ to CF₄ ranges between about 1:1 and about 2:1. We have found that a plasma source gas comprising about 30 to about 70 volume % CH₂F₂, about 30 to about 70 volume % CF₄, and about 2 to about 20 volume % O₂ provides good (at least 2:1) selectivity for etching the silicon-containing dielectric layer relative to an overlying photoresist, as well as excellent etch profile control. More typically, the plasma source gas composition comprises about 50 to about 70 volume % CH₂F₂, about 30 to about 50 volume % CF₄, and about 5 to about 15 volume % O₂. Typically, the sidewall angle for a patterned line ranges from about 84° to about 92°.

The plasma source gas composition may further include a nonreactive diluent gas such as helium, argon, neon, xenon, or krypton, by example and not by way of limitation. Often, the nonreactive diluent gas is helium. Helium is typically present in the source gas at a concentration within the range of about 50 to about 70 volume %. Often, the plasma source gas is selected to include about 10 to about 25 volume % CH₂F₂, about 10 to about 25 volume % CF₄, about 2 to about 10 volume % O₂, and about 50 to about 70 volume % helium.

The present etch method works particularly well when performed in a semiconductor processing chamber having a decoupled plasma source. Typical process conditions for etching of a silicon-containing dielectric material, according to the present embodiment method, in a decoupled plasma chamber (such as a CENTURA® DPS II™), are provided in Table Two, below:

TABLE TWO
Typical Process Conditions for Etching
of a Silicon-Containing Dielectric Material

| | Range of | | Advantageous |
|---|---|---|---|
| | Process | Typical Process | Process |
| Process Parameter | Conditions | Conditions | Conditions |
| CH₂F₂ Flow Rate (sccm) | 10-100 | 10-100 | 30-60 |
| CF₄ Flow Rate (sccm) | 30-100 | 30-100 | 30-60 |
| O₂ Flow Rate (sccm) | 3-30 | 3-30 | 5-20 |
| He Flow Rate (sccm) | 0-200 | 0-200 | 0-200 |
| Process Chamber | 3-20 | 4-10 | 4-10 |
| Pressure | | | |
| (mTorr) | | | |
| Plasma Source Power | 200-1800 | 300-1500 | 500-1000 |
| (W) | | | |
| Substrate Bias Power | 30-400 | 50-300 | 150-250 |
| (W) | | | |
| Substrate Temperature | 20-80 | 20-80 | 40-60 |
| (° C.) | | | |
| Etch Time Period (sec)* | 40-100 | 40-100 | 40-100 |

*For a 2000 Å thick silicon nitride layer.

The etch method described above works particularly well in combination with a photoresist which is sensitive to 248 nm radiation, of the kind commonly used in the art. Such photoresists are available from AZ Electronic Materials/Clariant (Somerville, N.J.) and Shipley, Inc. (Marlboro, Mass.), by way of example and not by way of limitation.

The method provides a selectivity for etching a silicon-containing dielectric layer relative to such a photoresist of about 2:1 or better. The method also provides an etch profile sidewall angle ranging from 84° to 92° between the etched silicon-containing dielectric layer and an underlying horizontal layer in the semiconductor structure. In addition, the method provides an etched sidewall roughness of about 5 nm or less.

Although the Examples above are described with reference to the use of a silicon-containing dielectric material as a hard mask in the etching of a gate structure, the etch chemistry and processing conditions described above can be used any time a silicon-containing dielectric material is used as a masking layer, for example, in the etching of a shallow trench or other semiconductor feature.

The above described exemplary embodiments are not intended to limit the scope of the present invention, as one skilled in the art can, in view of the present disclosure expand such embodiments to correspond with the subject matter of the invention claimed below.

We claim:

1. A method of pattern etching a layer of a silicon-containing dielectric material on a semiconductor substrate, wherein a patterned photoresist layer overlies said silicon-containing dielectric layer, said method comprising exposing said silicon-containing dielectric layer to a plasma generated from a source gas comprising CH₂F₂, CF₄, and O₂, wherein a volumetric ratio of CH₂F₂ to CF₄ is within the range of about 1:2 to about 3:1, and wherein O₂ comprises about 2 to about 20 volume % of the plasma source gas.

2. The method of claim 1, wherein said silicon-containing dielectric material is selected from the group consisting of silicon nitride, silicon oxide, silicon oxynitride, and combinations thereof.

3. The method of claim 1, wherein a volumetric ratio of CH₂F₂ to CF₄ is within the range of about 1:2 to about 2:1.

4. The method of claim 3, wherein a volumetric ratio of CH₂F₂ to CF₄ is within the range of about 1:1 to about 2:1.

5. The method of claim 1, wherein said source gas comprises about 30 to about 70 volume % CH₂F₂, about 30 to about 70 volume % CF₄, and about 2 to about 20 volume % O₂.

6. The method of claim 6, wherein said source gas comprises about 50 to about 70 volume % CH₂F₂, about 30 to about 50 volume % CF₄, and about 5 to about 15 volume % O₂.

7. The method of claim 1, wherein said source gas further includes helium.

8. The method of claim 7, wherein said helium is present in said source gas at a concentration within the range of about 50 to about 70 volume %.

9. The method of claim 8, wherein said source gas comprises about 10 to about 25 volume % CH₂F₂, about 10 to about 25 volume % CF₄, about 2 to about 10 volume % O₂, and about 50 to about 70 volume % helium.

10. The method of claim 1, wherein said photoresist is sensitive to 248 nm radiation.

11. The method of claim 1, wherein said silicon-containing dielectric layer is used as a hard mask during pattern etching of an underlying semiconductor structure, and wherein said semiconductor structure includes features having a feature size of about 0.13 μm or larger.

12. The method of claim 1, wherein said silicon-containing dielectric layer has a thickness within the range of about 1000 Å to about 2500 Å.

13. The method of claim 1, wherein etching is performed at a process chamber pressure within the range of about 4 mTorr to about 10 mTorr.

14. The method of claim 1, wherein said method is performed in a semiconductor processing chamber having a decoupled plasma source.

15. The method of claim 1, wherein said method provides a selectivity for etching said silicon-containing dielectric layer relative to said photoresist of at least 2:1.

16. The method of claim 1, wherein said method provides a sidewall etch profile angle ranging from 84° to 92° between said etched silicon-containing dielectric layer and an underlying horizontal layer.

17. A method of pattern etching a layer of silicon nitride on a semiconductor substrate, wherein a patterned photoresist layer overlies said silicon nitride layer, said method comprising exposing said silicon nitride layer to a plasma generated from a source gas comprising CH₂F₂, CF₄, and O₂, wherein a volumetric ratio of CH₂F₂ to CF₄ is within the range of about 1:2 to about 3:1, and wherein O₂ comprises about 2 to about 20 volume % of the plasma source gas.

18. The method of claim 1, wherein a volumetric ratio of CH₂F₂ to CF₄ is within the range of about 1:2 to about 2:1.

19. The method of claim 18, wherein a volumetric ratio of CH₂F₂ to CF₄ is within the range of about 1:1 to about 2:1.

20. The method of claim 1, wherein said source gas comprises about 30 to about 70 volume % CH₂F₂, about 30 to about 70 volume % CF₄, and about 2 to about 20 volume % O₂.

21. The method of claim 20, wherein said source gas comprises about 50 to about 70 volume % CH₂F₂, about 30 to about 50 volume % CF₄, and about 5 to about 15 volume % O₂.

22. The method of claim 1, wherein said source gas further includes helium.

23. The method of claim 22, wherein said helium is present in said source gas at a concentration within the range of about 50 to about 70 volume %.

24. The method of claim 23, wherein said source gas comprises about 10 to about 25 volume % CH₂F₂, about 10 to about 25 volume % CF₄, about 2 to about 10 volume % O₂, and about 50 to about 70 volume % helium.

25. The method of claim 1, wherein said photoresist is sensitive to 248 nm radiation.

26. The method of claim 1, wherein said silicon nitride layer is used as a hard mask during pattern etching of an underlying semiconductor structure, and wherein said semiconductor structure includes features having a feature size of about 0.13 μm or larger.

27. The method of claim 1, wherein said silicon nitride layer has a thickness within the range of about 1000 Å to about 2500 Å.

28. The method of claim 1, wherein etching is performed at a process chamber pressure within the range of about 4 mTorr to about 10 mTorr.

29. The method of claim 1, wherein said method is performed in a semiconductor processing chamber having a decoupled plasma source.

30. The method of claim 1, wherein said method provides a selectivity for etching said silicon nitride layer relative to said photoresist of at least 2:1.

31. The method of claim 1, wherein said method provides a sidewall etch profile angle ranging from 84° to 92° between said etched silicon nitride layer and an underlying horizontal layer.
